(19) United States
(12) Patent Application Publication
(10) Pub. No.: US 2017/0084873 A1
(43) Pub. Date: Mar. 23, 2017

(54) ORGANIC LIGHT-EMITTING DISPLAY DEVICE

(71) Applicant: Shenzhen China Star Optoelectronics Technology Co., Ltd., Shenzhen, Guangdong (CN)

(72) Inventor: Chao XU, Shenzhen (CN)

(21) Appl. No.: 14/893,628

(22) PCT Filed: Sep. 24, 2015
(86) PCT No.: PCT/CN2015/090566

§ 371 Date: Nov. 24, 2015

(30) Foreign Application Priority Data
Sep. 22, 2015 (CN) 201510605162.2

(51) Int. Cl. H01L 51/52; H01L 51/50; H01L 51/00

(52) U.S. Cl. CPC H01L 51/5275; H01L 51/0096; H01L 51/5056; H01L 51/5088; H01L 51/5092; H01L 51/5072; H01L 51/5221

(57) ABSTRACT

An organic light-emitting display device includes a transparent glass substrate; a light-extraction layer used to conduct light emitted from a light-emitting layer to the transparent glass substrate; a first electrode layer; the light-emitting layer; a second electrode layer; the light-emitting layer is clamped between the first electrode layer and the second electrode layer; the light-extraction layer is a transparent material layer and is saw-teeth shaped; and a refractive index of the light-extraction layer is greater than that of the first electrode layer.

### BACKGROUND OF THE INVENTION

Field of the Invention

The present invention relates to the technical field of organic light-emitting technology, and more particularly to an organic light-emitting display device.

Description of the Related Art

At present, Organic Light-emitting Diode (OLED) display has become a new generation display technology due to its characteristics of being self-luminous without using backlight sources, having a simple, thin and light structure, with fast response, wide viewing angles, low cost, and being able to achieve a flexible display structure. In addition, the investment cost on the equipment for manufacturing such display devices is lower than that on traditional liquid crystal display devices, therefore Organic Light-emitting Diode display has progressively become the main force of third-generation display in the field of display technology.

Although organic light-emitting diodes have many advantages over other light sources, there are still shortcomings in the organic light-emitting diodes, such as low light extraction rate. Light generated by the light-emitting layer of the organic light-emitting diode is reflected and refracted by a contact surface between an ITO film and glass substrate and a contact surface between the glass substrate and air, therefore most of the light cannot be emitted into air, thereby leads to low light extraction rate. This shortcoming has seriously limited the development of organic light-emitting diodes. Although conventional technologies provide many technical solutions to enhance the light extraction rate of organic light-emitting diodes, most of the solutions are complicated in process with high manufacturing cost.

### SUMMARY OF THE INVENTION

An objective of the present invention is to provide an organic light-emitting display device which greatly with a greatly-increased light extraction rate.

The technical solutions of the present invention are as follows:

An organic light-emitting display device including:

a transparent glass substrate, wherein a side of the transparent glass substrate is in contact with air;

a light-extraction layer being formed on another side of the transparent glass substrate and being used to conduct light emitted from a light-emitting layer to the transparent glass substrate;

a first electrode layer formed on a bottom surface of the light-extraction layer and having a flat surface;

the light-emitting layer covering a bottom surface of the first electrode layer for emitting light;

a second electrode layer being formed on a bottom surface of the light-emitting layer, wherein the light-emitting layer is clamped between the first electrode layer and the second electrode layer; wherein

the light-extraction layer is a transparent material layer; a refractive index of the light-extraction layer is greater than that of the first electrode layer; the light-extraction layer has a cross-section with a plurality of periodically-arranged saw-teeth; each of the saw-teeth has an isosceles triangle shape in cross section; the isosceles triangle shapes are identical.

Preferably, a base angle of the isosceles triangle shape is determined by the respective refractive index of the first electrode layer, the light-extraction layer and the transparent glass substrate, and the law of refraction.

Preferably, a height of the isosceles triangle shape is less than a thickness of the first electrode layer.

Preferably, a base of the isosceles triangle shape is parallel to a horizontal surface of the transparent glass substrate.

Preferably, the light-extraction layer is made of zinc oxide.

Preferably, the light-extraction layer is made of titanium dioxide.

Preferably, the first electrode layer is an anode layer; a hole transport layer and a hole injection layer are successively formed between the light-emitting layer and the anode layer.

Preferably, the second electrode layer is a cathode layer; an electron transport layer and an electron injection layer are successively formed between the light-emitting layer and the cathode layer.

Preferably, the second electrode layer is made of aluminum metallic material.

An organic light-emitting display device includes:

a transparent glass substrate, wherein a side of the transparent glass substrate is in contact with air;

a light-extraction layer being formed on another side of the transparent glass substrate and being used to conduct light emitted from a light-emitting layer to the transparent glass substrate;

a first electrode layer formed on a bottom surface of the light-extraction layer and having a flat surface;

the light-emitting layer covering a bottom surface of the first electrode layer for emitting light;

a second electrode layer being formed on a bottom surface of the light-emitting layer, wherein the light-emitting layer is clamped between the first electrode layer and the second electrode layer; wherein

the light-extraction layer is a transparent material layer; a refractive index of the light-extraction layer is greater than that of the first electrode layer.

Preferably, the light-extraction layer has a cross-section with a plurality of periodically-arranged saw-teeth; each of the saw-teeth has an isosceles triangle shape in cross section; the isosceles triangle shapes are identical.

Preferably, a base angle of the isosceles triangle shape is determined by the respective refractive index of the first electrode layer, the light-extraction layer and the transparent glass substrate, and the law of refraction.

Preferably, a height of the isosceles triangle shape is less than a thickness of the first electrode layer.

Preferably, a base of the isosceles triangle shape is parallel to a horizontal surface of the transparent glass substrate.

Preferably, the light-extraction layer is made of zinc oxide.

Preferably, the light-extraction layer is made of titanium dioxide.

Preferably, the first electrode layer is an anode layer; a hole transport layer and a hole injection layer are successively formed between the light-emitting layer and the anode layer.

Preferably, the second electrode layer is a cathode layer; an electron transport layer and an electron injection layer are successively formed between the light-emitting layer and the cathode layer.

Preferably, the second electrode layer is made of aluminum metallic material.

The present invention provides the following advantage:

That the light-extraction layer of the organic light-emitting display device has a refractive index greater than that of the first electrode layer and has a greater light transmittance effectively prevents light reflection and light refraction from occurring, thereby greatly enhancing light extraction rate of the organic light-emitting display device.

### BRIEF DESCRIPTION OF THE DRAWINGS

FIG. 1 is a cross-sectional view of an organic light-emitting diode device according to a preferred embodiment of the present invention, showing the path of light when refraction occurs at surfaces of an anode layer and a light-extraction layer;

FIG. 2 is a cross-sectional view of an organic light-emitting diode device according to prior art, showing the path of light when total internal reflection occurs at surfaces of an anode layer and a transparent glass substrate;

FIG. 3 is a schematic diagram showing the path of light generated by an organic light-emitting diode device according to a preferred embodiment of the present invention.

### DETAILED DESCRIPTION OF THE PREFERRED EMBODIMENTS

The foregoing objects, features and advantages adopted by the present invention can be best understood by referring to the following detailed description of the preferred embodiments and the accompanying drawings. Furthermore, the directional terms described in the present invention, such as upper, lower, front, rear, left, right, inner, outer, side and etc., are only directions referring to the accompanying drawings, so that the used directional terms are used to describe and understand the present invention, but the present invention is not limited thereto.

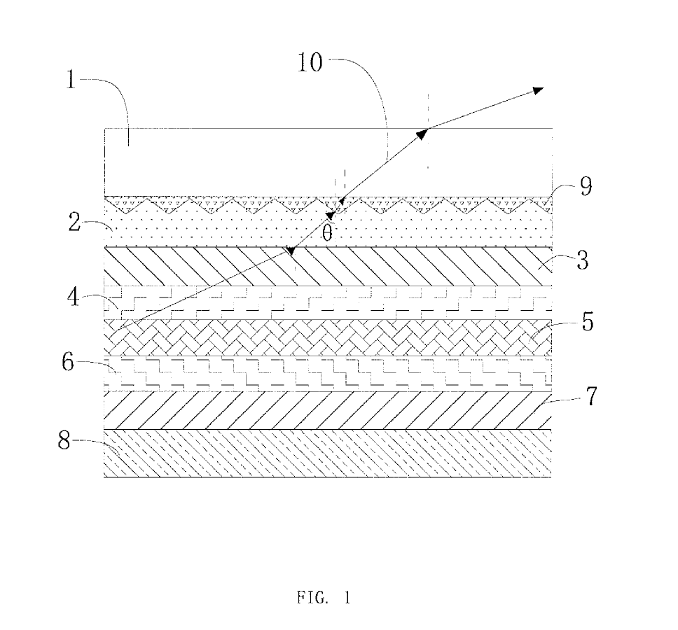

With reference to FIG. 1, FIG. 1 is a cross-sectional view of an organic light-emitting diode device according to a preferred embodiment of the present invention, showing the path of light when refraction occurs at surfaces of a first electrode layer 2 and a light-extraction layer 9, wherein 9 represents the angle between incident light 10 in the first electrode layer 2 and a normal line where total internal reflection will occur at the interface between the first electrode layer 2 and a transparent glass substrate 1 for the incident light 10 with such angle. As shown in FIG. 1, the light emitted by a light-emitting layer 5 of the organic light-emitting diode device travels in a direction towards the first electrode layer 2. A second electrode 8 is non-transparent. Layers of the organic light-emitting diode device from top to bottom are as follows: a transparent glass substrate 1, a light-extraction layer 9, a first electrode layer 2, a hole transport layer 3, a hole injection layer 4, a light-emitting layer 5, an electron injection layer 6, an electron transport layer 7, and a second electrode layer 8.

The transparent glass substrate 1 of the present invention has one side in contact with air, and another side facing the light-extraction layer 9. Light emitted from the light-emitting layer 5 travels through the light-extraction layer 9, then enters the transparent glass substrate 1, and finally exits into air.

The light-extraction layer 9 of the present invention may be formed on the another side of the transparent glass substrate 1 via a physical vapor deposition method and is used to conduct light emitted from a light-emitting layer 5 to the transparent glass substrate 1, wherein the light-extraction layer 9 may be a transparent material layer, and a refractive index of the light-extraction layer 9 is greater than that of the first electrode layer 2. Preferably, the light-extraction layer 9 has a cross-section with a plurality of periodically-arranged saw-teeth, and each of the saw-teeth has an isosceles triangle shape in cross section; the isosceles triangle shapes are identical. Preferably, the light-extraction layer 9 is made of zinc oxide or titanium dioxide, wherein the refractive index of zinc oxide or titanium dioxide is about 2.0. The determination of the range of the base angles of the isosceles triangle shape will be discussed in more detail later.

In the present invention, a height of the isosceles triangle shape is preferably less than a thickness of the first electrode layer 2. A base of the isosceles triangle shape is parallel to a horizontal surface of the transparent glass substrate. The base angle portion of the isosceles triangle shape of the present invention is not directly in contact with the transparent glass substrate so as to prevent incident light 10 from being directly illuminated on the transparent glass substrate 1 at the base angle portion of the isosceles triangle shape and causing total internal reflection.

The first electrode layer 2 of the present invention is formed on a bottom surface of the light-extraction layer 9 and has a flat surface. The first electrode layer 2 is preferably an anode layer. The first electrode 2 may be made of transparent indium tin oxide (ITO). Since the refractive index of ITO is about 1.8, and the refractive index of the light-extraction layer 9 is about 2.0, the refractive index of the light-extraction layer 9 is greater than that of the first electrode layer 2. Based on the law of refraction, when light passes through an A medium and enters a B medium, and the refractive index of the A medium is less than that of the B medium, the angle of refraction of the light is smaller than the angle of incidence, and total internal reflection will not occur. It can be seen from this that when the light emitted by the light-emitting layer 5 passes through the first electrode layer 2 with a smaller refractive index and enters the light-extraction layer with a larger refractive index, the angle of refraction of the light will be smaller than the angle of incidence. Therefore the light of the light-emitting layer 5 will bend towards the center of the transparent glass substrate 1 such that the light-emitting efficiency of the light-emitting layer 5 will be greatly increased.

In the present invention, the hole transport layer 3 and the hole injection layer 4 are successively formed between the light-emitting layer 5 and the first electrode layer 2.

In the present invention, the light-emitting layer 5 covers a bottom surface of the first electrode layer 2 for emitting light beams.

In the present invention, the second electrode layer 8 is formed on a bottom surface of the light-emitting layer 5. The light-emitting layer is clamped between the first electrode layer 2 and the second electrode layer 8.

In the present invention, the second electrode layer 8 is preferably a cathode layer. The electron transport layer 6 and the electron injection layer 7 are successively formed between the light-emitting layer 5 and the second electrode layer 8. The second electrode layer 8 reflects light which is emitted by the light-emitting layer 8 towards the second electrode layer 8. The second electrode layer 8 is preferably made of aluminum metallic material since aluminum has a great light reflection effect.

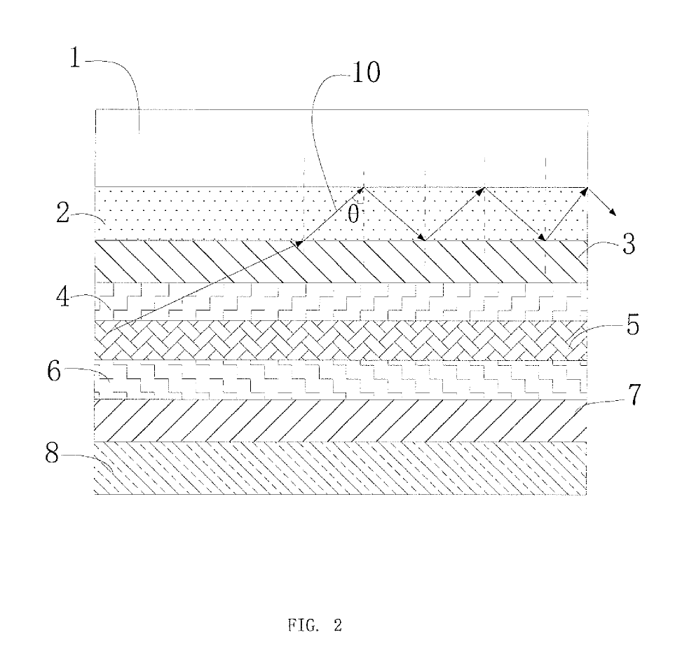

With reference to FIG. 2, FIG. 2 is a cross-sectional view of an organic light-emitting diode device according to prior art, wherein 9 represents the angle between incident light 10 in the first electrode layer 2 and a normal line where total internal reflection will occur at the interface between the first electrode layer 2 and a transparent glass substrate 1 for the light 10 with such angle. As shown in FIG. 2, a conventional organic light-emitting diode device according to prior art includes a transparent glass substrate 1, a first electrode layer, a hole transport layer 3, a hole injection layer 4, a light-emitting layer 5, an electron injection layer 6, an electron transport layer 7, and a second electrode layer 8. The conventional organic light-emitting diode device differs from the organic light-emitting diode device of the present invention in that: the conventional organic light-emitting diode device does not have a light-extraction layer 9 which has a refractive index larger than that of the first electrode layer 2 between the transparent glass substrate 1 and the anode layer. Since the refractive index of the transparent glass substrate 1 is only about 1.5 and is smaller than the refractive index of the first electrode layer 2 (ITO layer), when the light from the light-emitting layer 5 travels towards the interface between the first electrode layer 2 and the transparent glass substrate 1, the light will refract away from the normal line so that most of the light will be lost, and some of the light will be reflected due to total internal reflection. In contrast, since the organic light-emitting diode device of the present invention has the light-extraction layer 9 having a saw-teeth shape, and the refractive index of the light-extraction layer 9 is larger than that of the first electrode layer 2, total internal reflection will not occur, and the light from the light-emitting layer 5 will refract towards the center of the transparent glass substrate 1 such that the light-emitting efficiency of the light-emitting layer 5 will be greatly increased.

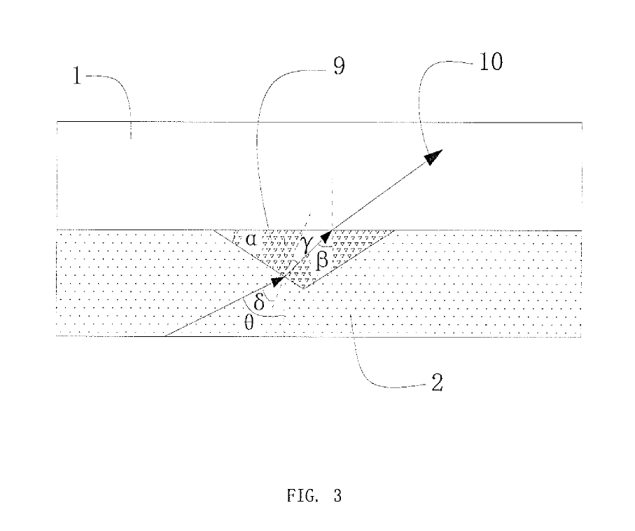

With reference to FIG. 3, FIG. 3 shows the path of light generated by an organic light-emitting diode device according to the present invention, wherein θ represents the angle between incident light 10 in the first electrode layer 2 and a normal line where total internal reflection will occur at the interface between the first electrode layer 2 and a transparent glass substrate 1 for the incident light with such angle. In addition, δ represents the angle of incidence of the incident light 10 at the boundary between the first electrode layer 2 and the leg side of the isosceles triangle shape; γ represents the angle of refraction related to the angle of incidence δ; β represents the angle of incidence at the boundary between the light-extraction layer 9 and the transparent glass substrate 1; a represents the base angle of the isosceles triangle shape. It can be seen from FIG. 3 that since the device has the light-extraction layer 9 mounted between the first electrode layer 2 and the transparent glass substrate 1, and the refractive index of the light-extraction layer 9 is larger than that of the first electrode layer 2, when the incident light 10 passes through the first electrode layer 2 and enters the light-extraction layer 9, the incident light 10 will refract on the boundary between the anode layer and the light-extraction layer 9 where the angle of refraction is smaller than the angle of incidence, such that the light-exiting direction of the incident light is directed towards the center of the transparent glass substrate 1, thereby increasing light-emitting efficiency.

In the present invention, the base angle a of the isosceles triangle shape is determined by the respective refractive index of the first electrode layer 2, the light-extraction layer 9 and the transparent glass substrate 1, and the law of refraction. For example, assume that the refractive index of the first electrode layer 2 is N1; the refractive index of the light-extraction layer 9 is N2; and the refractive index of the transparent glass substrate 1 is N3, wherein N2>N1 and N2<N3. As shown in FIG. 3, combining the law of refraction and geometric operations, a few formulas can be obtained as follows:

Based on the law of refraction:

sinδ/sinγ=N2/N1 (1);

To meet the condition that the incident light 10 can enter the transparent glass substrate 1 from the light-extraction layer 9:

sinβ<N3/N2 (2);

From geometric operations:

β=α+γ (3);

From formulas \textcircled{1}, \textcircled{2} and \textcircled{3}, a result can be obtained as follows:

α<arcsin (N3/N2)−arcsin {(N1/N2)sinδ}.

In conclusion, although the present invention has been described with reference to the preferred embodiment thereof, it is apparent to those skilled in the art that a variety of modifications and changes may be made without departing from the scope of the present invention which is intended to be defined by the appended claims.

1. An organic light-emitting display device, comprising:
a transparent glass substrate, wherein a side of the transparent glass substrate is in contact with air;
a light-extraction layer being formed on another side of the transparent glass substrate and being used to conduct light emitted from a light-emitting layer to the transparent glass substrate;
a first electrode layer formed on a bottom surface of the light-extraction layer and having a flat surface;
the light-emitting layer covering a bottom surface of the first electrode layer for emitting light;
a second electrode layer being formed on a bottom surface of the light-emitting layer, wherein the light-emitting layer is clamped between the first electrode layer and the second electrode layer; wherein
the light-extraction layer is a transparent material layer; a refractive index of the light-extraction layer is greater than that of the first electrode layer; the light-extraction layer has a cross-section with a plurality of periodically-arranged saw-teeth; each of the saw-teeth has an isosceles triangle shape in cross section; the isosceles triangle shapes are identical.

2. The organic light-emitting display device as claimed in claim 1, wherein the image grayscale value is an average value of all of the pixel grayscale values of the original image inputted by the liquid crystal display panel;
a base angle of the isosceles triangle shape is determined by the respective refractive index of the first electrode layer, the light-extraction layer and the transparent glass substrate, and the law of refraction.

3. The organic light-emitting display device as claimed in claim 1, wherein a height of the isosceles triangle shape is less than a thickness of the first electrode layer.

4. The organic light-emitting display device as claimed in claim 1, wherein a base of the isosceles triangle shape is parallel to a horizontal surface of the transparent glass substrate.

5. The organic light-emitting display device as claimed in claim 1, wherein the light-extraction layer is made of zinc oxide.

6. The organic light-emitting display device as claimed in claim 1, wherein the light-extraction layer is made of titanium dioxide.

7. The organic light-emitting display device as claimed in claim 1, wherein the first electrode layer is an anode layer; a hole transport layer and a hole injection layer are successively formed between the light-emitting layer and the anode layer.

8. The organic light-emitting display device as claimed in claim 1, wherein the second electrode layer is a cathode layer; an electron transport layer and an electron injection layer are successively formed between the light-emitting layer and the cathode layer.

9. The organic light-emitting display device as claimed in claim 1, wherein the second electrode layer is made of aluminum metallic material.

10. An organic light-emitting display device, comprising:
a transparent glass substrate, wherein a side of the transparent glass substrate is in contact with air;
a light-extraction layer being formed on another side of the transparent glass substrate and being used to conduct light emitted from a light-emitting layer to the transparent glass substrate;
a first electrode layer formed on a bottom surface of the light-extraction layer and having a flat surface;
the light-emitting layer covering a bottom surface of the first electrode layer for emitting light;
a second electrode layer being formed on a bottom surface of the light-emitting layer, wherein the light-emitting layer is clamped between the first electrode layer and the second electrode layer; wherein
the light-extraction layer is a transparent material layer; a refractive index of the light-extraction layer is greater than that of the first electrode layer.

11. The organic light-emitting display device as claimed in claim 10, wherein the light-extraction layer has a cross-section with a plurality of periodically-arranged saw-teeth; each of the saw-teeth has an isosceles triangle shape in cross section; the isosceles triangle shapes are identical.

12. The organic light-emitting display device as claimed in claim 11,
wherein a base angle of the isosceles triangle shape is determined by the respective refractive index of the first electrode layer, the light-extraction layer and the transparent glass substrate, and the law of refraction.

13. The organic light-emitting display device as claimed in claim 11, wherein a height of the isosceles triangle shape is less than a thickness of the first electrode layer.

14. The organic light-emitting display device as claimed in claim 11, wherein a base of the isosceles triangle shape is parallel to a horizontal surface of the transparent glass substrate.

15. The organic light-emitting display device as claimed in claim 10, wherein the light-extraction layer is made of zinc oxide.

16. The organic light-emitting display device as claimed in claim 10, wherein the light-extraction layer is made of titanium dioxide.

17. The organic light-emitting display device as claimed in claim 10, wherein the first electrode layer is an anode layer; a hole transport layer and a hole injection layer are successively formed between the light-emitting layer and the anode layer.

18. The organic light-emitting display device as claimed in claim 10, wherein the second electrode layer is a cathode layer; an electron transport layer and an electron injection layer are successively formed between the light-emitting layer and the cathode layer.

19. The organic light-emitting display device as claimed in claim 10, wherein the second electrode layer is made of aluminum metallic material.
